(19) United States
(12) Patent Application Publication
(10) Pub. No.: US 2009/0011564 A1
(43) Pub. Date: Jan. 8, 2009

(54) Method of forming a gate oxide layer

(75) Inventor: Min-Liang Chen, Hsinchu (TW)

Correspondence Address: Joe McKinney Muncy, PO Box 1364, Fairfax, VA, 22038-1364, US

(73) Assignee: ProMOS Technologies Inc.

(21) Appl. No.: 11/902,460

(22) Filed: Sep. 21, 2007

(30) Foreign Application Priority Data
Jul. 2, 2007 (TW) 96124021

(51) Int. Cl. H01L 21/336

(52) U.S. Cl. 438/287; 257/E21.423

(57) ABSTRACT

A nitrogen implantation to a substrate on the edges of an active area is added before filling an insulating layer in a trench during a shallow trench isolation process to reduce the thickness of a gate oxide formed later on the edges of the active area.

### CROSS-REFERENCE TO RELATED APPLICATION

This application claims the priority benefit of Taiwan application serial no. 96124021, filed Jul. 2, 2007, the full disclosure of which is incorporated herein by reference.

### BACKGROUND

1. Field of Invention

The present invention relates to a semiconductor process. More particularly, the present invention relates to a method of fabricating a semiconductor device.

2. Description of Related Art

Along with the progress of the semiconductor technology, the line width of the semiconductor integrated circuit has been decreasing. Hence, the sensitivity of the semiconductor device to the thickness of a gate oxide is also increased.

FIGS. 1A-1F are cross sectional diagrams showing a conventional process for forming shallow trench isolation. In FIG. 1A, a pad oxide layer 105 and a silicon nitride layer 110 are sequentially formed on a substrate 100. Then a photolithography and an etching processes are performed to pattern the silicon nitride layer 11, the pad oxide layer 105 and the substrate 100 to form a trench 115 in the substrate 100.

In FIG. 1B, the silicon nitride layer 110 is etched by hot phosphoric acid to draw back the sidewalls of the silicon oxide layer 110 from the edges of the trench 115. In FIG. 1C, a liner oxide layer 120 is formed on the surface of the trench 115 by thermal oxidation.

In FIG. 1D, a silicon oxide layer is deposited on the substrate 100 and the trench 115 by high-density plasma chemical vapor deposition. A chemical mechanical polishing is performed to remove the silicon oxide layer higher than the level of the silicon nitride layer 110 to form a silicon oxide plug 130.

In FIG. 1E, the silicon nitride layer 110 and the pad oxide layer 105 are sequentially removed by wet etching. In FIG. 1F, the exposed surface of the substrate 100 is oxidized by thermal oxidation to form a gate oxide layer 135.

However, the surface of the gate oxide layer 135 is not planar. The thickness of the gate oxide layer 135 is apparently larger than that on the rim of the silicon oxide plug 130.

According to the developing trend of the dynamic random access memory (DRAM), the narrowest line width is about 0.37 μm in the active areas of peripheral logic devices for 140 nm semiconductor process. The narrowest line width is about 0.33 μm in the active area of peripheral logic devices for 120 nm semiconductor process. The narrowest line width is about 0.29 μm in the active area of peripheral logic devices for 110 nm semiconductor process. Hence, when the line width in the active area on peripheral logic device is less than 0.3 μm, the driving current of devices on both memory area and peripheral area can be effectively increased by applying the present invention, and the performances of the memory product can thus be further increased.

### SUMMARY

According an embodiment of this invention, a method of forming a gate oxide layer is provided.

A buffer layer and a hard mask layer are sequentially formed on a substrate. The hard mask layer, the buffer layer and the substrate are sequentially patterned to form a trench in the substrate for defining an active area on the substrate. The hard mask layer is partially removed to draw back the sidewalls of the hard mask layer from the edge of the trench to expose the edge of the active area. A shielding layer is formed on the surface of the trench. Nitrogen ions are implanted into the edge of the active area. An insulating plug is formed in the trench to fill the trench. The hard mask layer and the buffer layer on the active area are sequentially removed. A gate oxide layer is formed on the active area.

### BRIEF DESCRIPTION OF THE DRAWINGS

The invention can be more fully understood by reading the following detailed description of the embodiment, with reference made to the accompanying drawings as follows:

FIGS. 1A-1F are cross sectional diagrams showing a conventional process of fabricating a shallow trench isolation; and

FIGS. 2A-2F are diagram showing a process of fabricating a gate oxide layer according to one embodiment of this invention.

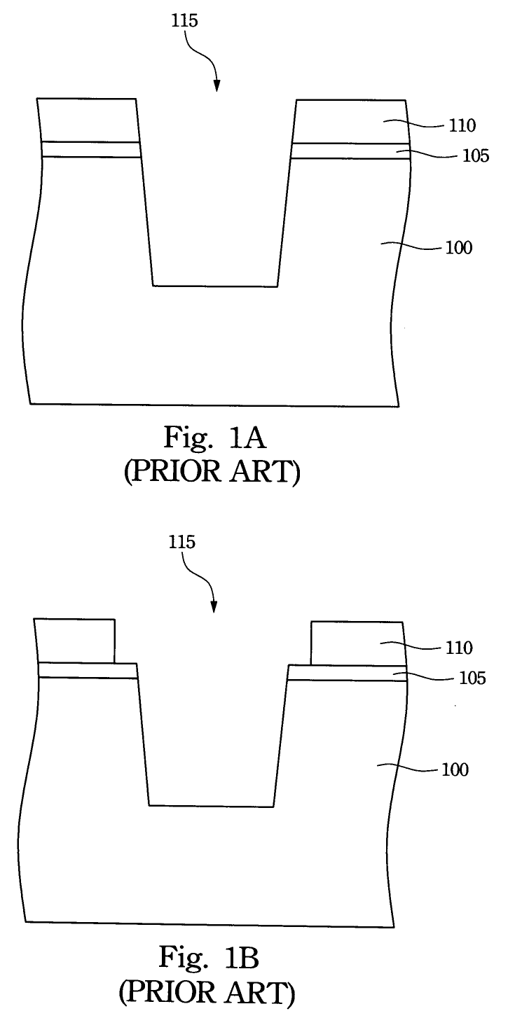

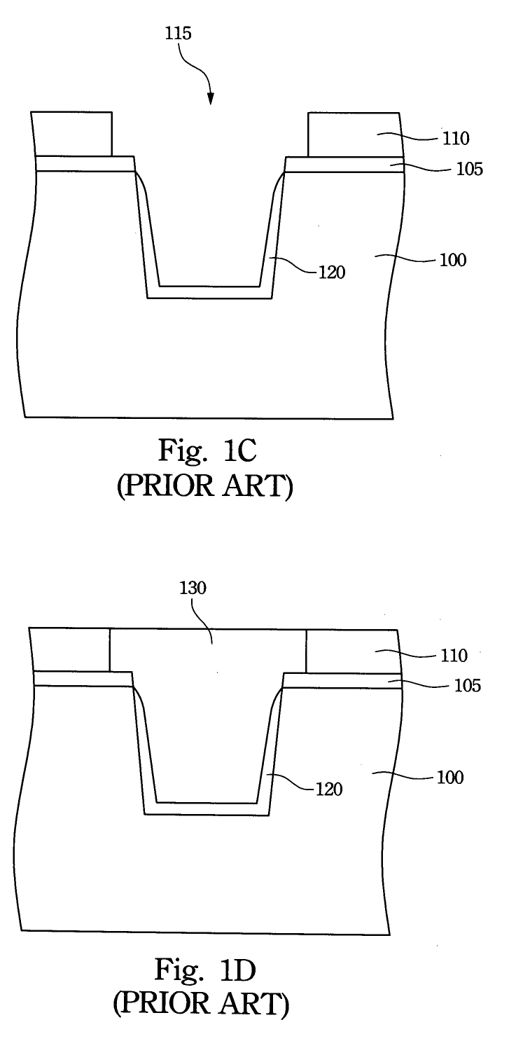

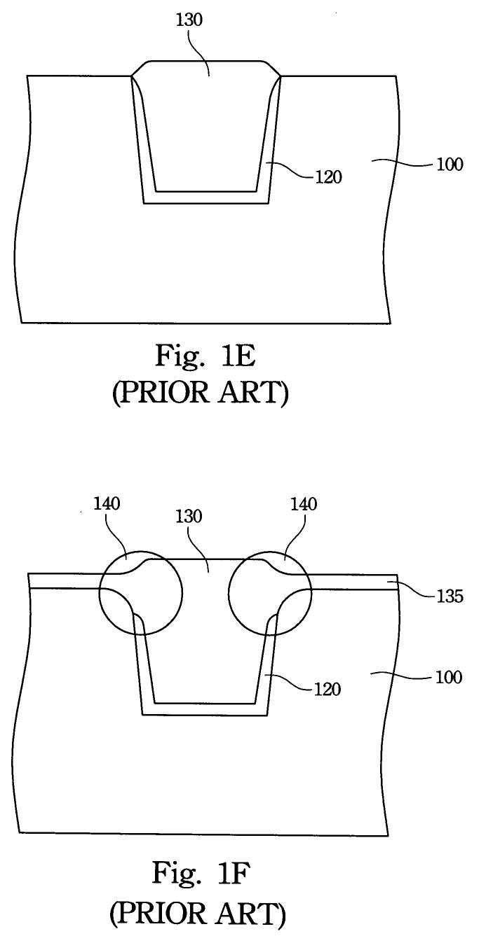

### DETAILED DESCRIPTION

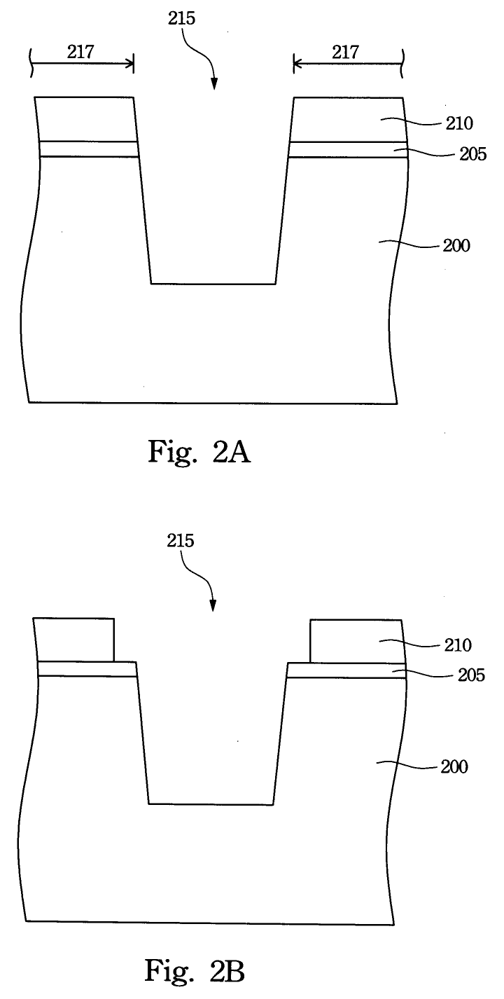

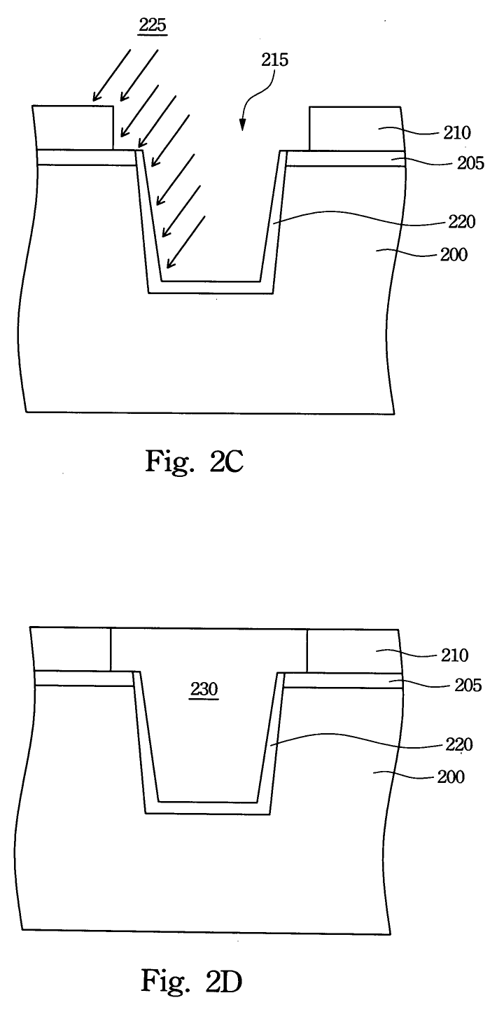

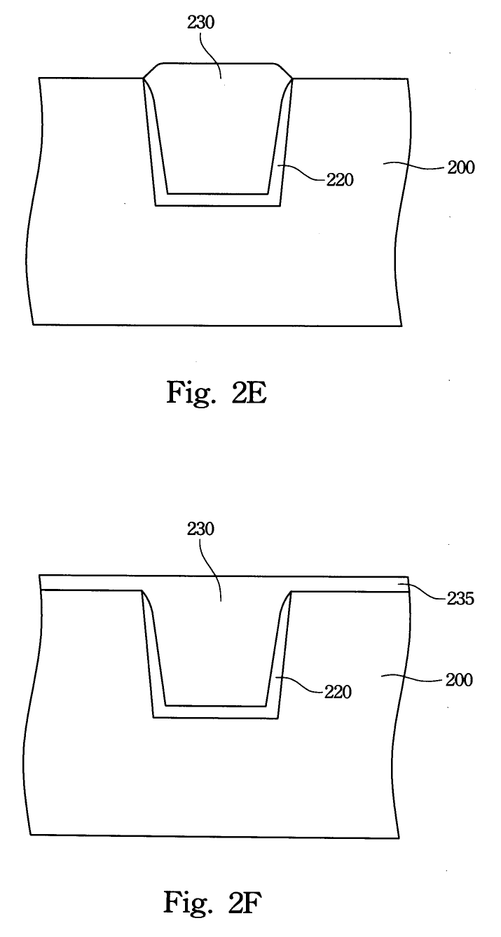

FIGS. 2A-2F are diagram showing a process of fabricating a gate oxide layer according to one embodiment of this invention.

In FIG. 2A, a buffer layer 205 and a hard mask layer 210 are sequentially formed on a substrate 200. The hard mask layer 210, the buffer layer 205 and the substrate 200 are sequentially patterned to form a trench 215 in the substrate 200 for defining an active area 217 on the substrate 200. The substrate 200 can be, for example, a silicon substrate or other proper semiconductor substrates. The buffer layer 205 can be, for example, a pad oxide layer formed by thermal oxidation. The hard mask layer 210 can be, for example, a silicon nitride layer formed by chemical vapor deposition.

In FIG. 2B, the hard mask layer 210 is partially removed to draw back the sidewalls of the hard mask layer 10 from the edge of the trench 215 to expose the edge of the active area 217. The removing method can be, for example, wet etching. For example, a silicon nitride layer can be etched by hot phosphoric acid or other proper etchants.

In FIG. 2C, a shielding layer 220 is formed on the surface of the trench 215. Nitrogen ions 225 are implanted into the edge of the active area 217. The implantation angle is about 20-24 degrees, and the implantation dose is about 6×10¹⁴-2.6×10¹⁵ cm⁻². The shielding layer 220 can be, for example, silicon oxide layer formed by thermal oxidation to protect the substrate 200 from being damaged and deep ion penetration caused by the so called channel effect.

In FIG. 2D, an insulating layer is formed to fill the trench 215 and then planarized by, for example, chemical mechanical polishing, to form an insulating plug 230. The insulating layer can be, for example, a silicon oxide layer formed by chemical vapor deposition.

In FIG. 2E, the hard mask layer 210 and the buffer layer 205 on the active area 217 are sequentially removed. In FIG. 2F, a gate oxide layer 235 is formed on the active area 217 by thermal oxidation.

Since one additional nitrogen ions 225 implantation process has been proceeded on the edges of the active area 217 (illustrated in FIG. 2C), the speed of thermal oxidation on the edges of active area 217 is reduced, so the thickness of the gate oxide layer 235 on the edges of the active areas 217 can be reduced. Therefore, the thickness of the gate oxide layer 235 can be more uniform, which increases the driving current on the edges of active areas 217 and thus increases the driving current of the MOS transistor.

Subsequently, a gate can be formed on the active area 217, and ions are implanted into the active area of the substrate by using the gate as implantation mask to form a source and a drain. Since the following processes are well known by persons skilled in the semiconductor processes, the descriptions of the following processes are omitted here.

Some experimental results are listed in Table 1. Each value in Table 1 was obtained by averaging 2 to 3 measurements. The implantation angle to the edges of active areas is 24 degrees deviated from the normal line toward 2, 90, 80, and 270 degrees respectively. In Table 1, the thickness of the gate oxide layer on the edges of the active areas can be decreased by increasing the implantation dosage.

| Active area | Exp 1 | Exp 2 | Exp 3 |
|---|---|---|---|
| Doping energy on the edges (KeV) | — | 15 | 15 |
| Doping dosage on the edges (cm⁻²) | — | 8 × 10¹⁴ | 1.6 × 10¹⁵ |
| Thickness of gate oxide layer on the | 30 | 30 | 30 |
| centers (Å) | | | |
| Thickness of gate oxide layer on the edges | 56.4 | 48 | 46.5 |
| (Å) | | | |
| Thickness ratio of the gate oxide layer on | 1.88 | 1.60 | 1.55 |
| the edges over the gate oxide layer on the | | | |
| centers | | | |

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of forming a gate oxide layer, the method is suitably applied on fabricating a semiconductor device having a line width less than 0.3 μm, the method comprising:
providing a substrate sequentially having a pad oxide and a silicon nitride thereon and having a trench therein;
partially removing the silicon nitride layer to draw back the sidewalls of the silicon nitride layer from the edge of the trench;
forming a thermal oxide layer on the surface of the trench;
implanting nitrogen ions into the edge of the trench;
forming a silicon oxide plug in the trench to fill the trench;
sequentially removing the silicon oxide layer and the pad oxide layer; and
forming a gate oxide layer on the exposed surface of the substrate.

2. The method of claim 1, further comprising:
forming a gate on the gate oxide layer; and
implanting the substrate by using the gate as implantation mask to form a source and a drain.

3. A method of forming a gate oxide layer, the method is suitably applied on fabricating a semiconductor device having a line width less than 0.3 μm, the method comprising:
sequentially forming a buffer layer and a hard mask layer on a substrate;
sequentially patterning the hard mask layer, the buffer layer and the substrate to form a trench in the substrate for defining an active area on the substrate;
partially removing the hard mask layer to draw back the sidewalls of the hard mask layer from the edge of the trench to expose the edge of the active area;
forming a shielding layer on the surface of the trench;
implanting nitrogen ions into the edge of the active area;
forming an insulating plug in the trench to fill the trench;
sequentially removing the hard mask layer and the buffer layer on the active area; and
forming a gate oxide layer on the active area.

4. The method of claim 3, further comprising:
forming a gate on the active area; and
implanting the substrate under the active are by using the gate as an implantation mask to form a source and a drain.

5. The method of claim 3, wherein the buffer layer is a silicon oxide layer.

6. The method of claim 5, wherein the forming method of the silicon oxide layer is thermal oxidation.

7. The method of claim 3, wherein the hard mask layer is silicon nitride layer.

8. The method of claim 7, wherein the forming method of the silicon nitride layer is chemical vapor deposition.

9. The method of claim 3, wherein the shielding layer is silicon oxide layer.

10. The method of claim 9, wherein the forming method of the silicon oxide layer is thermal oxidation.

11. The method of claim 3, wherein the insulating plug is a silicon oxide plug.

12. The method of claim 11, wherein the forming method of the silicon oxide plug is chemical vapor deposition and chemical mechanical polishing sequentially.
